(19) United States
(12) Patent Application Publication
(10) Pub. No.: US 2026/0157014 A1
(43) Pub. Date: Jun. 4, 2026

(54) VERTICAL STACKED MICRODISPLAY PANEL AND MANUFACTURING METHOD THEREOF

(71) Applicant: WAVELORD CO., LTD, Hwaseong-si (KR)

(72) Inventors: Juneo SONG, Suwon-si (KR); Ji Hyung MOON, Gunpo-si (KR); Tae Kyoung KIM, Osan-si (KR)

(73) Assignee: WAVELORD CO., LTD, Hwaseong-si (KR)

(21) Appl. No.: 19/333,441

(22) Filed: Sep. 19, 2025

(30) Foreign Application Priority Data
Dec. 3, 2024 (KR) 10-2024-0177192
Feb. 5, 2025 (KR) 10-2025-0014570

(51) Int. Cl. H10H 29/85; H01L 25/075; H10H 20/01; H10H 29/01; H10H 29/80

(52) U.S. Cl. CPC H10H 29/857; H10H 20/017; H10H 20/018; H10H 29/032; H10H 29/0364; H10H 29/832; H10H 29/962; H10W 90/00

(57) ABSTRACT

The present invention relates to a vertically stacked microdisplay panel, and the vertically stacked microdisplay panel includes a back wafer having a plurality of complementary metal-oxide semiconductor (CMOS) electrode pads aligned on an upper surface, a plurality of light-emitting diode (LED) stacks each including a light-emitting portion stacked in a vertical direction through a bonding layer and respectively aligned on the plurality of CMOS electrode pads, and a common electrode formed on the plurality of LED stacks, wherein the plurality of LED stacks include a first LED stack including a first light-emitting portion that emits a first color, a second LED stack including a second light-emitting portion that emits a second color, and a third LED stack including a third light-emitting portion that emits a third color, each of the plurality of LED stacks has a short passage formed in a region so that a current flows through the light-emitting portion where the short passage is not formed, thereby emitting only a specific color, the first light-emitting portion of the first LED stack is located above the second light-emitting portion of the second LED stack and the third light-emitting portion of the third LED stack, and the first light-emitting portion emits red light. According to the present invention, the light-emitting efficiency of red light in a vertically stacked tandem structure can be significantly improved.

### CROSS-REFERENCE TO RELATED APPLICATION

This application claims priority to and the benefit of Korean Patent Application No. 10-2025-0014570, filed on Feb. 5, 2025, the disclosure of which is incorporated herein by reference in its entirety.

### BACKGROUND

### Field of the Invention

The present invention relates to a vertically stacked microdisplay panel and a method of manufacturing the same, and more particularly, to a vertically stacked light-emitting diode on silicon (LEDOS) microdisplay panel in which the need for an alignment process of LED stacks and complementary metal-oxide semiconductor (CMOS) electrode pads is eliminated by using an engineering monolithic epitaxy wafer method, and a method of manufacturing the same.

### Discussion of Related Art

The types of implementation of the metaverse, which has recently been attracting attention, are classified into four types such as virtual reality (VR), augmented reality (AR), mixed reality (MR), and extended reality (XR). It is expected that the metaverse ecosystem will develop in the future, focusing on XR, which is a reality that combines VR, AR, and MR among the four types. In addition, in order to implement this effectively, devices (for example, smart glasses, head-mounted displays, and the like) that include microdisplays with a diagonal length of less than one inch as a core component, along with software for next-generation computing platforms that can deliver innovative user experiences, are required. Particularly, the development of high-performance microdisplay panel technology is absolutely necessary to provide XR users with the greatest immersion, visibility, and convenience and minimize dizziness.

As shown in FIG. 1, a conventional microdisplay panel 10 corresponds to a technology that combines a Si CMOS semiconductor wafer process and a high-resolution, high-brightness, ultra-small display process, and the conventional microdisplay panel 10 may have a structure in which a Si CMOS wafer 11 that has a (100) crystal plane of 4″ or more and is provided with a plurality of CMOS electrode pads 12, a plurality of microLED electrode pads 14, and a transparent wafer 13 of 4″ or more that is provided with a plurality of microLED chips 15 are bonded through a conductive bond 16. Meanwhile, the types of microdisplay panels expected to be applied to XR devices include liquid crystal (LC)-based LC on Si (LCOS), organic light-emitting diode (OLED)-based OLED on Si (OLEDOS), and LED on Si (LEDOS) based on ultra-small microLEDs with pixel sizes of less than 5 μm. In addition, in the case of VR where displays with a low pixel density are applied, the microdisplay panels are being developed and mass-produced mainly based on LCOS and OLEDOS.

However, with the advancement of metaverse implementation technology, the need for lightweight AR, MR, and XR devices to which microdisplay panels with a high pixel density are applied is gradually increasing. In addition, although the development of LEDOS technology, which is considered an ideal solution in theory based on its superior inorganic properties, is urgently needed to satisfy these needs, a microdisplay panel platform for this has not yet been established.

LEDOSs based on ultra-small microLEDs with pixel sizes of less than 5 μm have the advantages of an excellent power-to-performance ratio (P/P) and a short response speed when applied to XR devices, and since the LEDoSs are composed of inorganic materials, there are the advantages that the LEDoSs have a long lifespan, and have efficient power use to reduce heat generation and enable long-term battery life. Particularly, since XR devices have a very short distance between the display and the eyes, even a slight delay in image conversion can easily cause discomfort such as dizziness. Thus, LEDOS, which has a nanosecond response speed, is considered to be the most suitable for XR devices compared to LCOS and OLEDOS, which have a microsecond response speed.

Furthermore, it is evaluated that the biggest reason why LEDOS is attracting attention in AR, MR, and XR devices, unlike VR, is due to its brightness and luminous efficiency. Since smart glasses can be worn regardless of location, high brightness is essential for normal operation even in outdoor environments such as sunlight. In theory, microLEDs support brightness of tens to millions of nits, and since OLEDs are made of organic materials, whereas microLEDs are made of inorganic materials, the microLEDs also have the advantage of high luminous efficiency.

However, despite the above-described advantages, the biggest reason why LEDoSs based on ultra-small microLEDs with pixel sizes of less than 5 μm have not established as a major component of XR devices is the difficulty in mass production. In other words, LEDOS requires millions of ultra-small microLEDs to be fixed on a Si CMOS wafer so that the process difficulty is high and the yield is very low, which leads to increased manufacturing costs and high component prices. This is reflected in the final consumer price, and it is difficult to satisfy market demand as LEDOS is supplied as a high-priced XR device.

Meanwhile, as shown in FIG. 2, the development of LEDOS to which group III-V compound (GaN, GaP, and the like) microLED light sources are applied has been in progress until recently through traditional approaches such as (1) monolithic integration of wafers (or unit dies) composed of microLED arrays on CMOS wafers or (2) hybridization between wafers (or unit dies) on blue, green, and red light source wafers (or unit dies) on which CMOS wafers or microLED arrays are fabricated.

One of the biggest obstacles to the development of LEDOS to which blue, green, and red microLED light sources composed of group III-V compounds to date are applied is the difficulty in securing a solution for pixels of less than 5 μm. In addition, recently, 5 μm-level pixels have been successfully demonstrated using monolithic integration technology, and some demonstrators developed based on hybridization technology were fabricated using sapphire flip chips, achieving 10 μm-level pixels. Additionally, it has been demonstrated that it is possible to reduce pixels to the 5 μm level in the same way by using micro tube wiring in hybridization technology. However, both monolithic integration and hybridization technologies are impractical solutions with significant challenges in mass production in terms of quality and yield, making mass production difficult.

The above-described monolithic integration technology and hybridization technology have a common feature of separately designing and manufacturing a front plane wafer composed of a group III-V compound microLED array and a Si CMOS back plane wafer composed of numerous IC electrode pad arrays, and then assembling them. However, the microLED array manufactured at the unit die level or wafer level on the Si CMOS wafer needs to be ultra-finely aligned regardless of the method. Thus, in this case, alignment is limited to the precision of the process-related device, which has a significant impact on the pixel and inter-pixel distance (pitch) limitations, and mass production also becomes difficult. Accordingly, a new alternative solution that is capable of overcoming the above-described ultra-fine alignment constraints is required to manufacture LEDOS to which high-resolution, high-brightness, and high-speed driving blue, green, and red microLED light sources with pixels of less than 5 μm and pitches of less than 3 μm are applied.

Accordingly, although several impressive demonstrations with 6 μm pixels have been recently released using engineering monolithic epitaxy wafers manufactured through a low-temperature metal bonding process between a Si CMOS wafer and a microLED array wafer, mass production is considered impossible due to low quality and yield issues caused by low-temperature metal bonding and the use of small-diameter wafers of less than 6 inches. Above all, when fabricating ultra-fine pixels of less than 3 μm for microdisplays using conventional engineering monolithic epitaxy wafers using metal bonding, the patterning etching process faces even greater difficulties.

As another example, great progress has been made in solving the problem of limitations in the brightness and resolution of LEDOS to which group III-V compound microLED light sources are recently applied, and a novel engineered monolithic epitaxy wafer approach has been proposed that can provide high-volume, low-cost manufacturing solutions using 12-inch large-diameter Si CMOS wafers.

As shown in FIG. 3, the corresponding technology is specifically performed through the following four-step process using an engineering monolithic epitaxy wafer. (1) First, an LED epitaxy cut to a predetermined size (for example, 4 mm×6 mm) is aligned and bonded at a unit die level on a 12-inch large-diameter Si blanket wafer using an LED epitaxy wafer. Afterward, the growth wafer and buffer layer of the LED epitaxy are removed and then planarized to leave only an LED active layer of a predetermined thickness (for example, approximately 1.5 μm) on the large-diameter Si blanket wafer, and then the LED fab process in the form of a pixel chip is completed. (2) Subsequently, the Si blanket wafer with the completed pixel chip is bonded to a 12-inch CMOS IC Si wafer at the wafer level through multi-layer metal bonding. (3) Subsequently, the Si blanket wafer is removed. (4) Subsequently, the remaining process is finally performed on the CMOS IC Si wafer for the microLED array that functions as a pixel.

However, in step (1), when bonding the LED epitaxy unit die on the Si blanket wafer, there is a limitation that the alignment needs to be performed on a CMOS IC Si wafer of the same size to bond the LED epitaxy unit die on the Si blanket wafer. In addition, in step (2), when bonding with a multi-layer metal including a low-melting-point metal (Sn or In), there is a problem in that a phenomenon of overflowing low-melting-point metal components occurs relatively easily, resulting in a short circuit defect that is electrically connected between the microLED sub-pixel arrays in the panel or with the adjacent CMOS IC electrode pad array. Furthermore, in step (2), there is a problem that defects occur due to the difficulty in ultra-fine alignment wafer bonding between the Si blanket wafer (that is, front plane wafer) and the CMOS IC Si wafer due to the optically opaque nature of the Si blanket wafer and the multi-layer metal bonding layer. Here, the ultra-fine alignment means aligning the microLED array, which is a plurality (hundreds to tens of millions) of ultra-small pixel chips provided on a Si blanket wafer, and the CMOS IC electrode pad array provided on a CMOS IC Si wafer in a 1:1 ratio.

That is, although the engineering monolithic epitaxy wafer approach presented in the above-described technologies is evaluated to provide a solution that brings us one step closer to the implementation of LEDOS based on ultra-small microLEDs with pixel sizes of less than 5 μm, since there are quality and yield issues caused by the use of metals (low temperature, multi-layer) in wafer bonding, and it is very difficult to manufacture high-resolution microdisplays with ultra-fine pixels of less than 3 μm, and there are also problems with some alignment processes, new alternatives are needed.

In addition, since the conventional vertically stacked tandem structure of the microdisplays still uses a color filter to implement full color, there are disadvantages in terms of color quality, process complexity, and productivity.

Meanwhile, in a conventional microdisplay panel structure provided with a short passage as shown in FIG. 4, a first light-emitting portion 121 that emits red light, a second light-emitting portion 122 that emits green light, and a third light-emitting portion 123 that emits blue light are sequentially stacked, thereby emitting blue light from the uppermost portion. In this case, the red light emitted from the first light-emitting portion 121 is absorbed while passing through the second light-emitting portion 122 and the third light-emitting portion 123 so there is a problem that the efficiency of red light is relatively low in this structure.

Also, in order to solve this problem, when the third light-emitting portion 123 that emits blue light, the second light-emitting portion 122 that emits green light, and the first light-emitting portion 121 that emits red light are sequentially stacked, there is a problem that unwanted sub-pixel emission may occur due to light excitation in the second light-emitting portion 122 and the first light-emitting portion 121 on an upper portion by blue light with a short wavelength.

### RELATED ART DOCUMENT

### Patent Document

(Patent Document 0001) Korea Patent Publication No. 10-2018-0009116

### SUMMARY OF THE INVENTION

The present invention is directed to solving the above-described conventional problems, and providing a vertically stacked light-emitting diode on silicon (LEDOS) microdisplay panel which can significantly improve the light-emitting efficiency of red light in a vertically stacked tandem structure while eliminating the need for an alignment process of LED stacks and CMOS electrode pads by using an engineering monolithic epitaxy wafer method, and a method of manufacturing the same.

According to the present invention, there is provided a vertically stacked microdisplay panel including a back wafer having a plurality of complementary metal-oxide semiconductor (CMOS) electrode pads aligned on an upper surface, a plurality of light-emitting diode (LED) stacks each including a light-emitting portion stacked in a vertical direction through a bonding layer and respectively aligned on the plurality of CMOS electrode pads, and a common electrode formed on the plurality of LED stacks, wherein the plurality of LED stacks include a first LED stack including a first light-emitting portion that emits a first color, a second LED stack including a second light-emitting portion that emits a second color, and a third LED stack including a third light-emitting portion that emits a third color, each of the plurality of LED stacks has a short passage formed in a region so that a current flows through the light-emitting portion where the short passage is not formed, thereby emitting only a specific color, the first light-emitting portion of the first LED stack is located above the second light-emitting portion of the second LED stack and the third light-emitting portion of the third LED stack, and the first light-emitting portion emits red light.

Also, a width of the short passage may be formed to correspond to a width of the light-emitting portion.

Furthermore, the common electrode may be a negative electrode or a positive electrode.

According to the present invention, there is provided a method of manufacturing a vertically stacked microdisplay panel including a preparation step of preparing a plurality of front wafers including a support wafer and a light-emitting portion and a back wafer having a plurality of CMOS electrode pads aligned on an upper surface, a stacking step of vertically stacking a plurality of light-emitting portions on the support wafer by repeatedly bonding another front wafer on one front wafer through a bonding layer and then removing the support wafer of the other front wafer, a first processing step of forming a short passage in a partial region from one side of the plurality of stacked light-emitting portions, a bonding step of bonding the plurality of stacked light-emitting portions to the back wafer, and then removing the support wafer to stack the plurality of light-emitting portions on the back wafer, a second processing step of forming a short passage in a partial region from the other side of the plurality of stacked light-emitting portions, an etching step of etching the plurality of stacked light-emitting portions and separating the plurality of stacked light-emitting portions into preset units, thereby allowing the plurality of LED stacks to respectively aligned on the plurality of CMOS electrode pads, and a forming step of forming a common electrode on the plurality of LED stacks, wherein the plurality of LED stacks include a first LED stack including a first light-emitting portion that emits a first color, a second LED stack including a second light-emitting portion that emits a second color, and a third LED stack including a third light-emitting portion that emits a third color, each of the plurality of LED stacks has a short passage formed in a region so that a current flows through the light-emitting portion where the short passage is not formed, thereby emitting only a specific color, the first light-emitting portion of the first LED stack is located above the second light-emitting portion of the second LED stack and the third light-emitting portion of the third LED stack, and the first light-emitting portion emits red light.

Also, a width of the short passage may be formed to correspond to a width of the light-emitting portion.

Furthermore, the common electrode may be a negative electrode.

According to the present invention, there is provided a method of manufacturing a vertically stacked microdisplay panel including a preparation step of preparing a plurality of front wafers including a support wafer and a light-emitting portion and a back wafer having a plurality of CMOS electrode pads aligned on an upper surface, a stacking step of vertically stacking a plurality of light-emitting portions on the support wafer by repeatedly bonding another front wafer on one front wafer through a bonding layer and then removing the support wafer of the other front wafer, a first processing step of forming a short passage in a partial region from one side of the plurality of stacked light-emitting portions, a second processing step of forming a short passage in a partial region from the other side of the plurality of stacked light-emitting portions, a bonding step of bonding the plurality of stacked light-emitting portions to the back wafer, and then removing the support wafer to stack the plurality of light-emitting portions on the back wafer, an etching step of etching the plurality of stacked light-emitting portions and separating the plurality of stacked light-emitting portions into preset units, thereby allowing the plurality of LED stacks to be respectively aligned on the plurality of CMOS electrode pads, and a forming step of forming a common electrode on the plurality of LED stacks, wherein the plurality of LED stacks include a first LED stack including a first light-emitting portion that emits a first color, a second LED stack including a second light-emitting portion that emits a second color, and a third LED stack including a third light-emitting portion that emits a third color, each of the plurality of LED stacks has a short passage formed in a region so that a current flows through the light-emitting portion where the short passage is not formed, thereby emitting only a specific color, the first light-emitting portion of the first LED stack is located above the second light-emitting portion of the second LED stack and the third light-emitting portion of the third LED stack, and the first light-emitting portion emits red light.

Also, a width of the short passage may be formed to correspond to a width of the light-emitting portion.

Furthermore, the common electrode may be a positive electrode.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 shows the structure of a conventional microdisplay panel;

FIG. 2 shows a conventional light-emitting diode on silicon (LEDOS) development approach;

FIG. 3 shows an approach using a conventional engineering monolithic epitaxy wafer;

FIG. 4 shows the absorption of red light that occurs in a conventional microdisplay panel structure provided with a short passage;

FIG. 5 is a flowchart for describing a method of manufacturing a vertically stacked microdisplay panel according to a first embodiment of the present invention;

FIGS. 6 and 7 show a process of preparing a front wafer in the method of manufacturing a vertically stacked microdisplay panel according to the first embodiment of the present invention;

FIG. 8 shows a process of preparing a back wafer in the method of manufacturing a vertically stacked microdisplay panel according to the first embodiment of the present invention;

FIGS. 9 and 10 show a process of manufacturing a vertically stacked microdisplay panel according to the method of manufacturing a vertically stacked microdisplay panel according to the first embodiment of the present invention;

FIG. 11 shows a vertically stacked microdisplay panel according to the first embodiment of the present invention;

FIG. 12 is a flowchart for describing a method of manufacturing a vertically stacked microdisplay panel according to a second embodiment of the present invention;

FIGS. 13 and 14 show a process of preparing a front wafer in the method of manufacturing a vertically stacked microdisplay panel according to the second embodiment of the present invention;

FIGS. 15 and 16 show a process of manufacturing a vertically stacked microdisplay panel according to the method of manufacturing a vertically stacked microdisplay panel according to the second embodiment of the present invention; and

FIG. 17 shows a vertically stacked microdisplay panel according to the second embodiment of the present invention.

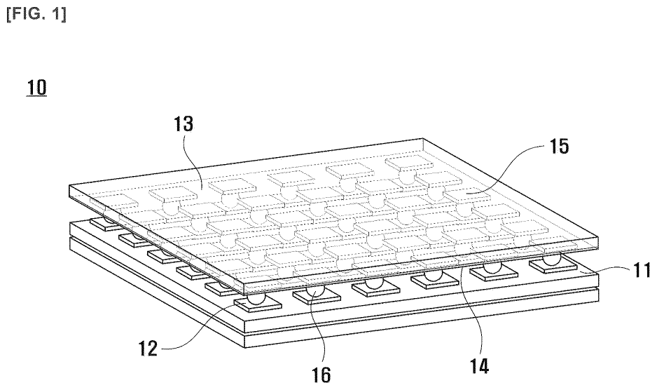

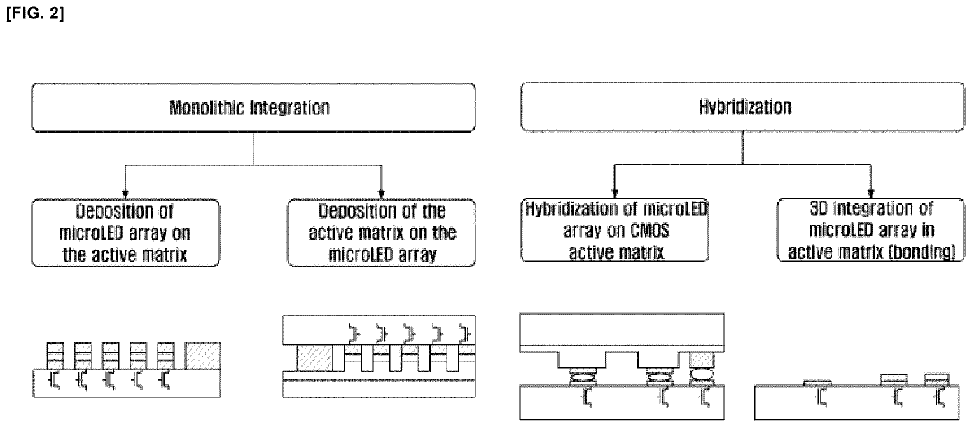

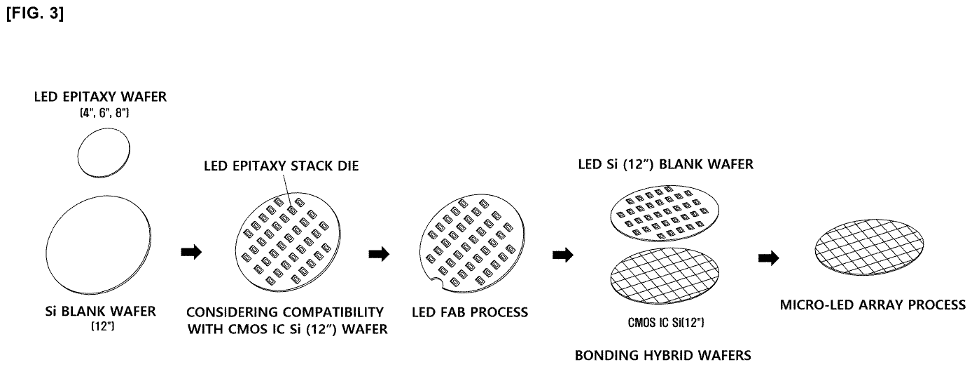

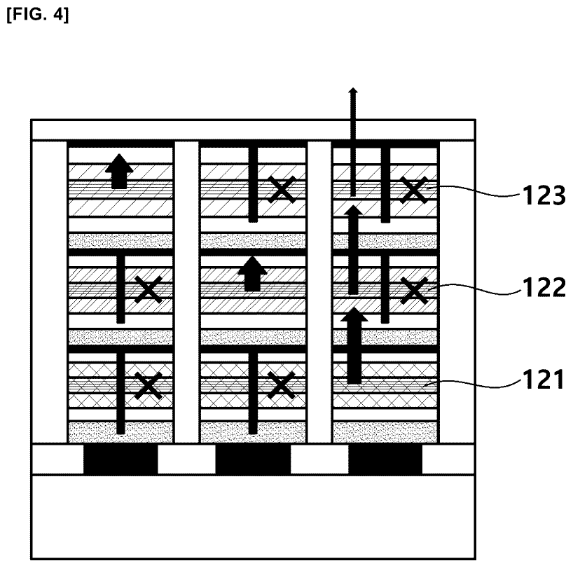

### DETAILED DESCRIPTION OF EXEMPLARY EMBODIMENTS

Hereinafter, some embodiments of the present invention will be described in detail through exemplary drawings. When assigning reference numerals to components of each of the drawings, it should be noted that identical components are denoted by the same reference numerals as much as possible even when they are shown on different drawings.

In addition, when describing embodiments of the present invention, when a detailed description of a related known configuration or function is determined to hinder understanding of the embodiment of the present invention, the detailed description is omitted.

Additionally, when describing components of embodiments of the present invention, terms such as first, second, A, B, (a), (b), and the like may be used. These terms are only intended to distinguish the components from other components, and the nature, order, or sequence of the components are not limited by the terms.

Hereinafter, a method S100 of manufacturing a vertically stacked microdisplay panel according to a first embodiment of the present invention will be described in detail with reference to the attached drawings.

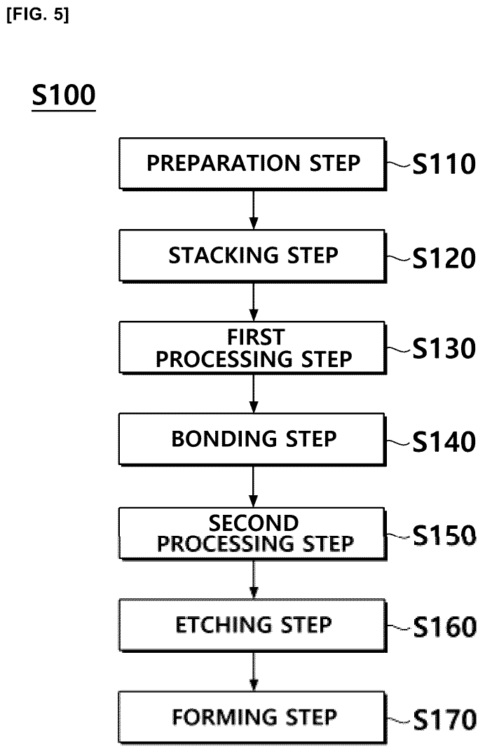

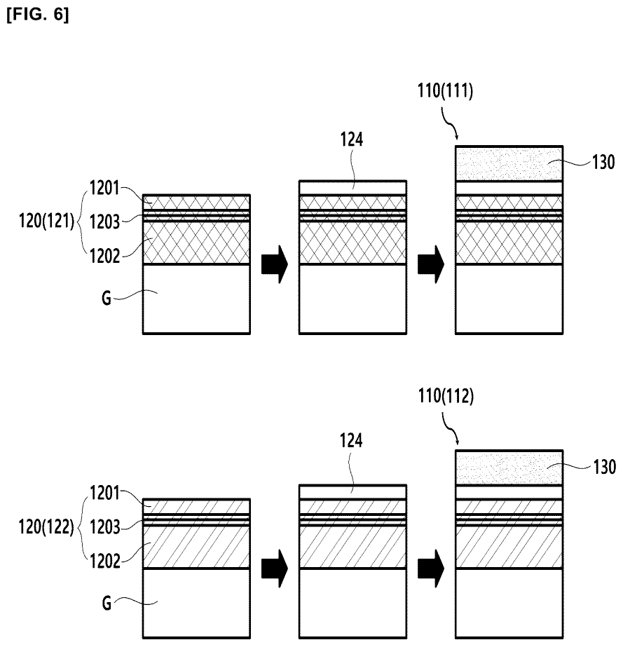

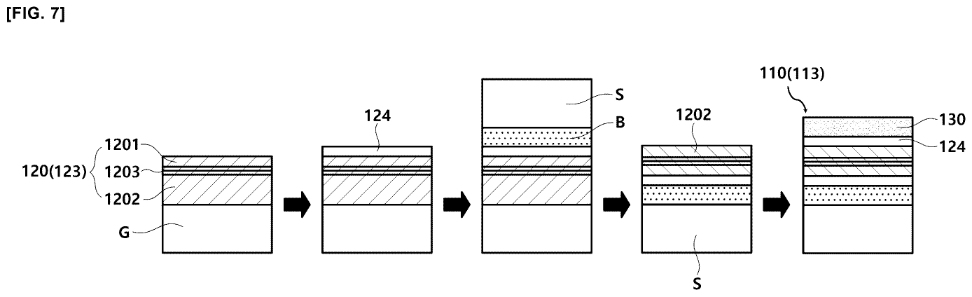

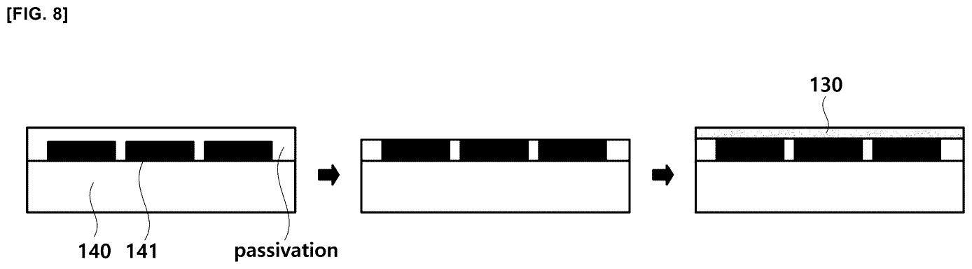

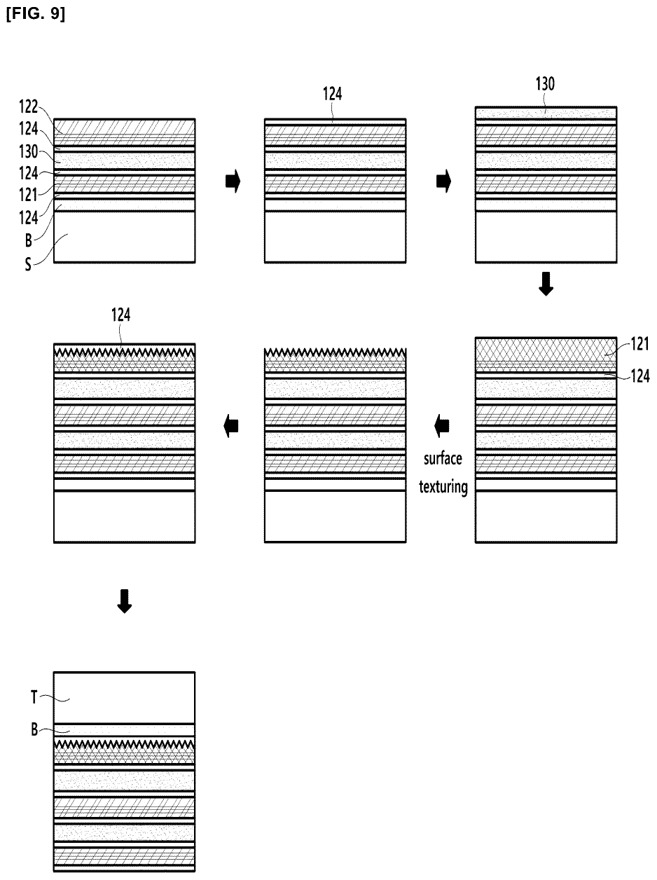

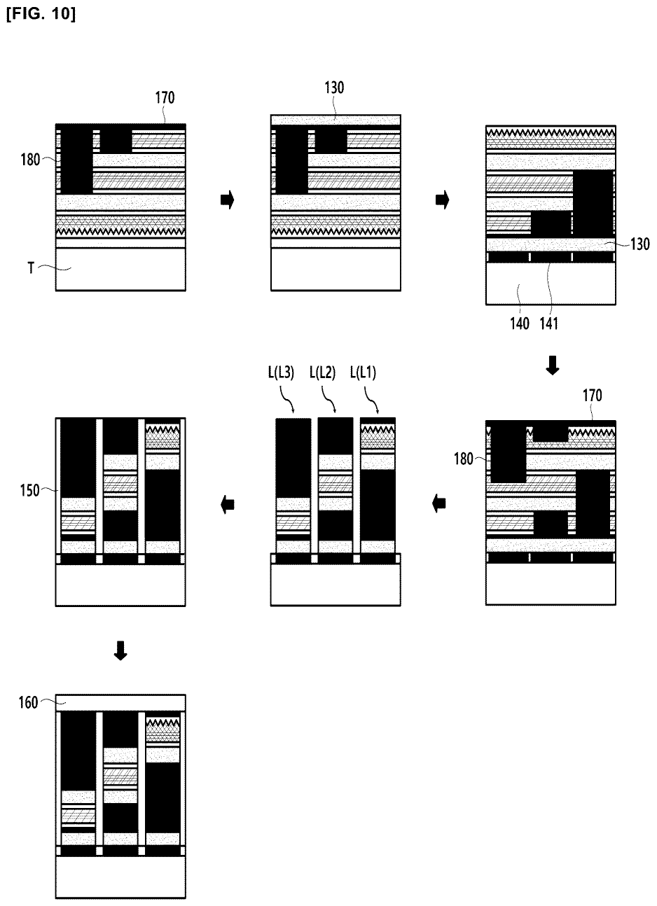

FIG. 5 is a flowchart for describing the method S100 of manufacturing a vertically stacked microdisplay panel according to the first embodiment of the present invention, FIGS. 6 and 7 show a process of preparing a front wafer 110 in the method S100 of manufacturing a vertically stacked microdisplay panel according to the first embodiment of the present invention, FIG. 8 shows a process of preparing a back wafer 140 in the method S100 of manufacturing a vertically stacked microdisplay panel according to the first embodiment of the present invention, and FIGS. 9 and 10 show a process of manufacturing a vertically stacked microdisplay panel according to the method S100 of manufacturing a vertically stacked microdisplay panel according to the first embodiment of the present invention.

As shown in FIGS. 5 to 10, the method S100 of manufacturing a vertically stacked microdisplay panel according to the first embodiment of the present invention, in which a common electrode 160 is a negative electrode, may include a preparation step S110, a stacking step S120, a first processing step S130, a bonding step S140, a second processing step S150, an etching step S160, and a forming step S170.

The preparation step S110 is a step of preparing a plurality of front wafers 110 and a back wafer 140.

The plurality of front wafers 110 are each for emitting different colors, and the plurality of front wafers 110 may include a first front wafer 111 for emitting a first color, a second front wafer 112 for emitting a second color different from the first color, and a third front wafer 113 for emitting a third color different from the first and second colors. Meanwhile, the first color, the second color, and the third color may be, for example, red, green, and blue, respectively, but are not limited thereto, and may include various other colors.

Here, the first front wafer 111 may include a support wafer S and a first light-emitting portion 121 disposed on an upper portion of the support wafer S, the second front wafer 112 may include a support wafer S and a second light-emitting portion 122 disposed on an upper portion of the support wafer S, and the third front wafer 113 may include a support wafer S and a third light-emitting portion 123 disposed on an upper portion of the support wafer S.

A light-emitting portion 120 generates light and may emit blue light, green light, or red light. In the present invention, when the light-emitting portion 120 emits blue light or green light, binary, ternary, or quaternary compounds such as InN, InGaN, GaN, AlGaN, AlN, and AlGaInN, which are group III (Al, Ga, and In) nitride semiconductors among group III-V compound semiconductors, may be disposed in an appropriate position and order on an initial growth wafer G and epitaxially grown.

Particularly, in order to emit blue or green light, a high-quality group III nitride semiconductor such as InGaN with a high In composition needs to be preferentially formed on an upper portion of a group III nitride semiconductor composed of GaN, AlGaN, AlN, or AlGaInN, but is not limited thereto.

In addition, in the present invention, when the light-emitting portion 120 emits red light, binary, ternary, and quaternary compounds such as InP, InGaP, GaP, AlInP, AlGaP, AlP, and AlGaInP, which are group III (Al, Ga, and In) phosphide semiconductors among group III-V compound semiconductors, may be disposed in an appropriate position and order on the initial growth wafer G and epitaxially grown. In addition, in recent years, in order to further improve the development of device and process technology and the value of display panel products, in the case of emitting red light, a high-quality group III nitride semiconductor such as InGaN with a high In composition of 30% or more, other than a group III phosphide semiconductor, may be preferentially formed on an upper portion of a group III nitride semiconductor composed of GaN, AlGaN, AlN, or AlGaInN.

Particularly, in order to emit red light, a high-quality group III phosphide semiconductor such as InGaP having a high In composition needs to be preferentially formed on an upper portion of a group III phosphide semiconductor composed of GaP, AlInP, AlGaP, AlP, AlGaInP, but is not limited thereto, and the group III nitride semiconductor is used as a basis for the description below.

More specifically, each of the light-emitting portions 120 may include, a first semiconductor region 1201 (for example, a p-type semiconductor region), an active region 1203 (for example, multi quantum wells, MQWs), and a second semiconductor region 1202 (for example, an n-type semiconductor region), have a structure in which the second semiconductor region 1202, the active region 1203, and the first semiconductor region 1201 are sequentially epitaxially grown on the growth wafer G, and ultimately have an overall thickness of about 5.0 to 8.0 μm typically, including a plurality of multi-layers of group III nitrides, but is not limited thereto.

Each of the first semiconductor region 1201, the active region 1203, and the second semiconductor region 1202 may be formed as a single layer or a plurality of layers. In addition, although not shown, before epitaxially growing the light-emitting portion 120 on an upper portion of the growth wafer G, necessary layers such as a buffer layer may be added to improve the quality of the epitaxially grown light-emitting portion 120. For example, the buffer layer may be configured to have a thickness of typically around 4.0 μm, including a nucleation layer NL and a compliant layer CL composed of an undoped semiconductor region to relieve stress and improve thin film quality. Additionally, when the growth wafer G is removed using a laser lift off (LLO) technique, a sacrificial layer SL may be provided between the nucleation layer and the undoped semiconductor region, and a seed layer may also function as the sacrificial layer.

The second semiconductor region 1202 has a second conductivity and may be formed on the growth wafer G. This second semiconductor region 1202 may have a thickness of 2.0 to 3.5 μm, and the surface may have nitrogen polarity (N-polarity).

The active region 1203 generates light by utilizing the recombination of electrons and holes and may be formed on the second semiconductor region 1202. The active region 1203 may have a thickness of several tens of nm in a plurality of layers.

The first semiconductor region 1201 has a first conductivity (p-type) and may be formed on the active region 1203. The first semiconductor region 1201 may have a thickness of several tens of nm to several μm in a plurality of layers, and the surface may have gallium polarity (Ga-polarity).

That is, the active region 1203 may be disposed between the first semiconductor region 1201 and the second semiconductor region 1202, and when holes in the first semiconductor region 1201, which is a p-type semiconductor region, and electrons in the second semiconductor region 1202, which is an n-type semiconductor region, recombine in the active region 1203, light may be generated.

Additionally, in the process of preparing the front wafer 110, an optically transparent and electrically conductive ohmic contact electrode 124 that is electrically connected to the light-emitting portion 120 by making ohmic contact with the light-emitting portion 120 may be formed on at least one of the upper and lower surfaces of the light-emitting portion 120, which will be described below.

The support wafer S supports the light-emitting portion 120 (first light-emitting portion 121, second light-emitting portion 122, or third light-emitting portion 123) disposed on an upper portion. When an initial growth wafer G is not removed, the growth wafer G may be the support wafer S, which is a separate wafer bonded to remove the initial growth wafer G.

As shown in FIG. 6, the process of manufacturing the first front wafer 111 in the present embodiment is as follows.

For the first front wafer 111 for emitting red light, a front wafer 110 in a p-side up form is prepared by sequentially epitaxially growing a second semiconductor region 1202, an active region 1203, and a first semiconductor region 1201 on a GaAs growth wafer G, forming a p-type ohmic contact electrode 124 having transparent conductivity on an upper surface of the first semiconductor region 1201, and then depositing and forming a bonding layer 130 having transparent conductivity on the ohmic contact electrode 124. In this case, the growth wafer G serves as the support wafer S, and the first front wafer 111 may have a structure in which the support wafer S, the light-emitting portion 120, the ohmic contact electrode 124, and the bonding layer 130 are sequentially stacked.

In addition, as shown in FIG. 6, the process of manufacturing the second front wafer 112 in the present embodiment is as follows.

For the second front wafer 112 for emitting green light, a front wafer 110 in a p-side up form is prepared by sequentially epitaxially growing a second semiconductor region 1202, an active region 1203, and a first semiconductor region 1201 on a sapphire (α-phase Al2O3) growth wafer G, forming a p-type ohmic contact electrode 124 having transparent conductivity on an upper surface of the first semiconductor region 1201, and then depositing and forming a bonding layer 130 having transparent conductivity on the ohmic contact electrode 124. In this case, the growth wafer G serves as the support wafer S, and the second front wafer 112 may have a structure in which the support wafer S, the light-emitting portion 120, the ohmic contact electrode 124, and the bonding layer 130 are sequentially stacked.

In addition, as shown in FIG. 7, the process of manufacturing the third front wafer 113 in the present embodiment is as follows.

For the third front wafer 113 for emitting blue light, after sequentially epitaxially growing a second semiconductor region 1202, an active region 1203, and a first semiconductor region 1201 on a sapphire (α-phase Al2O3) growth wafer G, a p-type ohmic contact electrode 124 having transparent conductivity is formed on an upper surface of the first semiconductor region 1201, and then a support wafer S and the ohmic contact electrode 124 are bonded through a bonding layer B. Afterward, the growth wafer G may be separated from the light-emitting portion 120 using a laser lift off (LLO) technique, the second semiconductor region 1202 may be etched to reduce the thickness of the second semiconductor region 1202, an n-type ohmic contact electrode 124 having transparent conductivity may be formed on the surface of the second semiconductor region 1202 whose thickness has been reduced, and a bonding layer 130 may be deposited and formed on the n-type ohmic contact electrode 124, thereby preparing a front wafer 110 in an n-side up form. In this case, the support wafer S may be formed of a Si material having a (111), (110) or (100) crystal plane, but is not limited thereto, and the third front wafer 113 may have a structure in which the support wafer S, the bonding layer B, the ohmic contact electrode 124, the light-emitting portion 120, the ohmic contact electrode 124, and the bonding layer 130 are sequentially stacked.

Meanwhile, in the case of green light and blue light, a blue or green light-emitting portion 120 may be formed on a Si growth wafer G having a (111) crystal plane instead of the sapphire (a-phase Al2O3) growth wafer G, and in this case, the Si growth wafer G may be separated and removed by a mechanical polishing technique or a chemical etching technique (chemical lift off, CLO).

Furthermore, in the present invention, the materials of the growth wafer G, the support wafer S, and/or the temporary wafer T may each be silicon (Si) or sapphire, but the selection of the materials may be determined according to a wafer bonding method.

For example, in the case of bonding at room temperature through a surface activation process (surface activated bonding), wafers of different materials such as silicon (Si) or sapphire may be selected regardless of the thermal expansion coefficient. However, when wafer bonding between the growth wafer G, the support wafer S, the temporary wafer T, and the back wafer 140, bonding may be performed at a temperature of 50° C. or higher, or when annealing at a temperature of 50° C. or higher without removing one wafer while bonding between wafers is performed, wafers of the same material need to be selected.

Meanwhile, in the above-described manufacturing process of the front wafer 110, before the ohmic contact electrode 124 is formed on the surface of the first semiconductor region 1201 or the surface of the second semiconductor region 1202, in the case where the surface of the first semiconductor region 1201 is exposed (p-side up form) or the surface of the second semiconductor region 1202 is exposed (n-side up form), the surfaces may be polished and smoothly planarized through mechanical polishing (MP) or chemical-mechanical polishing (CMP) so as to have a smooth surface.

In addition, the ohmic contact electrode 124 of the front wafer 110 is formed of a material having transparent conductivity. When the ohmic contact electrode 124 is formed to be in contact with the first semiconductor region 1201 which is a p-type semiconductor, the material of the ohmic contact electrode 124 may include NiO, PtO, PdO, AgO2, Au, Rh2O3, RuO2, In2O3, SnO2, ZnO, IZO, ITO, and IGZO. When the ohmic contact electrode 124 is formed to be in contact with the second semiconductor region 1202 which is an n-type semiconductor, the material of the ohmic contact electrode 124 may include TiN, CrN, VN, In2O3, SnO2, ZnO, IZO, ITO, and IGZO. Furthermore, since the surface of the second semiconductor region 1202 having nitrogen polarity (N-polarity) has a much higher surface roughness than the surface of the first semiconductor region 1201 having gallium polarity (Ga-polarity), it is preferable to introduce a chemical-mechanical polishing (CMP) process for polishing and flattening the surface of the second semiconductor region 1202 before forming the ohmic contact electrode 124 having transparent conductivity.

Additionally, the surface of the ohmic contact electrode 124 formed on the front wafer 110 may also be polished and smoothed through mechanical polishing (MP) or chemical-mechanical polishing (CMP).

The back wafer 140 is an active driving IC driven by an active matrix (AM) method, and refers to a CMOS wafer in which a plurality of CMOS electrode pads 141 are arranged on an upper surface in an array, as shown in FIG. 8. A passivation layer may be formed on an upper surface of the back wafer 140 so that upper surfaces of the plurality of CMOS electrode pads 141 are not exposed, and a portion of the passivation layer may be etched so that the plurality of CMOS electrode pads 141 are exposed when the front wafer 110 is bonded.

Here, the back wafer 140 may be prepared as a Si wafer having a (100) crystal plane, and may be prepared as an 8-inch or 12-inch Si wafer according to a standard CMOS IC process. However, considering that a typical LED wafer (front wafer 110) for bonding is 4 inches or 6 inches, the size of the back wafer is not particularly limited.

The stacking step S120 is a step of vertically stacking the plurality of light-emitting portions 120 on the support wafer S by repeatedly bonding another front wafer 110 on one front wafer 110 through the bonding layer 130 and then removing the support wafer S of the other front wafer 110.

Here, the bonding layer 130 may be formed of a ceramic material that is optically transparent and electrically conductive, that is, has transparent conductivity. Here, optically transparent means transparent (a transmittance of 80% or more) or translucent (semitransparent with a transmittance of 50% or more) within the wavelength range of light (including visible light) used in an optical exposure (photolithography) process, and electrically conductive means having an electrical resistance of less than 10−3 Ω/cm. The ceramic materials having transparent conductivity may include a transparent conductive oxide (TCO), a transparent conductive nitride (TCN), and a transparent conductive oxide nitride (TCON).

In this case, when the ceramic material is a transparent conductive oxide, the ceramic material may include In2O3, SnO2, ZnO, IZO, ITO, and IGZO, when the ceramic material is a transparent conductive nitride, the ceramic material may include TIN, CrN, and VN, and when the ceramic material is a transparent conductive oxide nitride, the ceramic material may include InON, SnON, ZnON, IZON, ITON, and IGZON.

As shown in FIG. 9, specifically, in the stacking step S120 in the present embodiment, first, the second front wafer 112 in a p-side up form that emits green light may be bonded to the third front wafer 113 in an n-side up form that emits blue light through the bonding layer 130, and then the support wafer S of the second front wafer 112 may be removed using laser lift-off or the like. Afterward, the second semiconductor region 1202 of the second light-emitting portion 122 exposed by removing the support wafer S may be etched to reduce its thickness, and then the n-type ohmic contact electrode 124 may be formed on the surface of the second semiconductor region 1202, and the bonding layer 130 may be deposited on the n-type ohmic contact electrode 124.

Subsequently, the first front wafer 111 in a p-side up form that emits red light may be bonded through the bonding layer 130, and then the support wafer S of the first front wafer 111 may be removed using chemical lift-off or the like. Afterward, the second semiconductor region 1202 of the first light-emitting portion 121 exposed by removing the support wafer S may be etched to reduce its thickness, and then the n-type ohmic contact electrode 124 may be formed on the surface of the second semiconductor region 1202. In this case, when etching the second semiconductor region 1202 of the first light-emitting portion 121, a surface texturing process may be performed on the surface of the second semiconductor region 1202.

Subsequently, the temporary wafer T may be bonded to the upper n-type ohmic contact electrode 124 through the bonding layer B, and then the lower support wafer S may be separated using laser lift-off, chemical lift-off, or the like and the bonding layer B may be removed. Then, heat treatment should be performed at a high temperature of 200 to 900° C. to improve the bonding strength of the transparent conductive ceramic bonding layer 130. That is, in the present invention, after all RGB light sources are stacked on the temporary wafer T, high-temperature heat treatment may be performed to secure the bonding strength between the RGB epitaxial layers, and then the RGB stacked structure may be bonded to the CMOS Si back wafer 140 at one time.

Through this, the temporary wafer T, the bonding layer B, the first light-emitting portion 121 having the ohmic contact electrode 124 formed on each of the upper and lower surfaces, the bonding layer 130, the second light-emitting portion 122 having the ohmic contact electrode 124 formed on each of the upper and lower surfaces, the bonding layer 130, and the third light-emitting portion 123 having the ohmic contact electrode 124 formed on each of the upper and lower surfaces are stacked in the vertical direction, and this stack may secure strong bonding strength between the RGB epitaxial layers through heat treatment at a high temperature.

Meanwhile, the stacking step S120 may utilize the property of smooth surfaces sticking to each other due to van der Waals forces without using high pressure or an external electric field. Accordingly, it is preferable to introduce a chemical-mechanical polishing (CMP) process before bonding the front wafers 110 to each other so that the roughness of each bonding surface is very low (Rq, <0.5 nm @ 2 μm×2 μm) and there are no particles such as impurities between the surfaces. To this end, in the stacking step S120, before bonding the front wafers 110 to each other, the surface of the bonding layer 130 of the front wafers 110 may be polished to a smooth flat surface through mechanical polishing (MP) or chemical-mechanical polishing (CMP).

The first processing step S130 is a step of forming a short passage 180 in a partial region from one side (that is, the third light-emitting portion 123 side) of the plurality of stacked light-emitting portions 120.

Specifically, in the first processing step S130, after forming a through hole to extend in the region where a first LED stack L1 is to be formed to pass through the third light-emitting portion 123, the ohmic contact electrode 124, and the bonding layer 130 on the upper and lower surfaces of the third light-emitting portion 123, and then pass through the second light-emitting portion 122 and the ohmic contact electrodes 124 on the upper and lower surfaces of the second light-emitting portion 122 (or pass through the bonding layer 130 below the second light-emitting portion 122, the through hole may be filled with an optically transparent and electrically conductive transmissive material to form a short passage 180. In addition, in the first processing step S130, after forming a through hole to extend in the region where a second LED stack L2 is to be formed to pass through the third light-emitting portion 123 and the ohmic contact electrodes 124 on the upper and lower surfaces of the third light-emitting portion 123 (or pass through the bonding layer 130 below the third light-emitting portion 123), the through hole may be filled with a conductive transmissive material to form a short passage 180.

In this case, a width of the through hole, that is, a width of the short passage 180, may be formed to correspond to a width of an LED stack L to be formed or a width of the light-emitting portion 120 of the formed LED stack L, but is not limited thereto.

Here, forming the short passage 180 after forming the through hole may be performing by filling the through hole with a conductive transmissive material in a direct self-align manner, or by filling this through hole with a conductive transmissive material in a liquid coating manner such as sol-gel, but is not limited thereto, and any method may be used to form the short passage 180 in the through hole.

Meanwhile, in the first processing step S130 of the present invention, the through hole may be filled with an optically transparent and electrically conductive material to form the short passage 180, and after filling the through hole, the material may remain on the surface of the bonding layer 130 or may be removed. In this case, when the material remains on the ohmic contact electrode 124 on the third light-emitting portion 123, a transmissive layer 170 may be formed. That is, both the short passage 180 and the transmissive layer 170 may be formed of an optically transparent and electrically conductive material.

When the short passage 180 and the transmissive layer 170 are formed of an optically transparent and electrically conductive material, it is preferable to form the short passage 180 and the transmissive layer 170 using a material having low resistance and high transmittance characteristics. These materials may include, but are not limited to, In2O3, SnO2, ZnO, IZO, ITO, and IGZO.

The bonding step S140 is a step in which, after the first processing step S130, the temporary wafer T on which the plurality of light-emitting portions 120 are vertically stacked is bonded to the back wafer 140 through the bonding layer 130, and then the temporary wafer T is removed.

After the temporary wafer T and the back wafer 140 are bonded, heat treatment of the bonding layer 130 should be performed at a temperature of less than 400° C. to prevent damage a CMOS circuit of the back wafer 140, and the removal of the temporary wafer T may be accomplished using techniques such as mechanical polishing (MP) and chemical lift off (CLO). Meanwhile, in the case where a sapphire temporary wafer T is used as the temporary wafer T, it is of course possible to remove the temporary wafer T using a laser lift off (LLO) technique.

Meanwhile, in the present invention, although an alignment process is required between the short passage 180 and the CMOS electrode pad 141 in the bonding step S140, high-precision bonding is possible because the light-emitting portion 120, the short passage 180, the transmissive layer 170, and the bonding layer 130 are all transparent in the visible light range.

Accordingly, in the present invention, the third light-emitting portion 123 that emits blue light, the second light-emitting portion 122 that emits green light, and the first light-emitting portion 121 that emits red light are sequentially stacked on the back wafer 140 in an n-side up form, and the upper surface of the first light-emitting portion 121 having nitrogen polarity may be surface textured.

The second processing step S150 is a step of forming the short passage 180 from the other side (that is, the first light-emitting portion 121 side) of the plurality of stacked light-emitting portions 120.

Specifically, in the second processing step S150, after forming a through hole to extend in the region where a third LED stack L3 is to be formed to pass through the first light-emitting portion 121, the ohmic contact electrodes 124 on the upper and lower surfaces of the first light-emitting portion 121, and the bonding layer 130 below the first light-emitting portion, and then pass through the second light-emitting portion 122 and the ohmic contact electrodes 124 on the upper and lower surfaces of the second light-emitting portion 122 (or pass through the bonding layer 130 below the second light-emitting portion 122), the through hole may be filled with an optically transparent and electrically conductive transmissive material to form the short passage 180. In addition, in the second processing step S150, after forming the through hole in the region where the second LED stack L2 is to be formed to pass through the first light-emitting portion 121 and the ohmic contact electrodes 124 on the upper and lower surfaces of the first light-emitting portion 121 (or pass through the bonding layer 130 below the first light-emitting portion 121), the through hole may be filled with a conductive transmissive material to form a short passage 180. In addition, in the second processing step S150, after filling the through hole with a conductive transmissive material, this material may be left on the ohmic contact electrode 124 so that a transmissive layer 170 may be formed in the region where the first LED stack L1 is to be formed.

In this case, a width of the through hole, that is, a width of the short passage 180, may be formed to correspond to a width of the LED stack L to be formed in the same manner as in the first processing step S130 or a width of the light-emitting portion 120 of the formed LED stack L, but is not limited thereto.

The etching step S160 is a step in which the plurality of light-emitting portions 120, the ohmic contact electrodes 124, and the bonding layers 130 which have been stacked are etched to separate the light-emitting portions 120, the ohmic contact electrodes 124, and the bonding layers 130 into preset units, thereby allowing the plurality of LED stacks L to be respectively disposed and aligned on the plurality of CMOS electrode pads 141.

That is, the etching step S160 is a step which vertically etches the light-emitting portion 120, the bonding layers 130, the ohmic contact electrodes 124, and the transmissive layer 170 until the surface or adjacent region of the back wafer 140 is exposed so that an array is formed, that is, the plurality of LED stacks L are aligned on upper portions of the aligned CMOS electrode pads 141. Here, the preset unit means a pixel or sub-pixel unit, and may mean the width (diameter) of the plurality of LED stacks L.

In this case, since the light-emitting portion 120, the bonding layer 130, the ohmic contact electrode 124, and the transmissive layer 170 of the present invention are all transparent, allowing visible light to pass therethrough, there is an advantage in that there is no alignment error issue in the exposure process. In addition, since both the bonding layer 130 and the ohmic contact electrode 124 of the present invention are made of a ceramic material rather than metals, there is an advantage in that etching is easy in the plasma dry process, and there is no problem in that etching byproducts are redeposited.

Meanwhile, the plurality of LED stacks L may include a first LED stack L1 for emitting only a first color, a second LED stack L2 for emitting only a second color, and a third LED stack L3 for emitting only a third color.

After the above-described etching step S160 has been performed, the first LED stack L1 may be formed to have a short passage 180 such that the region of the third light-emitting portion 123 including ohmic contact electrodes 124 on the upper and lower surfaces and the region of the second light-emitting portion 122 including ohmic contact electrodes 124 on the upper and lower surfaces are removed so that a current flows only through the first light-emitting portion 121 to emit only a first color, and when the transmissive layer 170 is formed on the first light-emitting portion 121, the transmissive layer 170 may transmit the first color generated in the first light-emitting portion 121.

In addition, the second LED stack L2 may be formed to have a short passage 180 such that the region of the first light-emitting portion 121 including ohmic contact electrodes 124 on the upper and lower surfaces and the region of the third light-emitting portion 123 including ohmic contact electrodes 124 on the upper and lower surfaces are removed so that a current flows only through the second light-emitting portion 122 to emit only a second color.

In addition, the third LED stack L3 may be formed to have a short passage 180 such that the region of the first light-emitting portion 121 including ohmic contact electrodes 124 on the upper and lower surfaces and the region of the second light-emitting portion 122 including ohmic contact electrodes 124 on the upper and lower surfaces are removed so that a current flows only through the third light-emitting portion 123 to emit only a third color and the transmissive layer 170 is formed below the third light-emitting portion 123.

Accordingly, the first LED stack L1 of the present invention may include only the first light-emitting portion 121 that emits red light, the second LED stack L2 may include only the second light-emitting portion 122 that emits green light, and the third LED stack L3 may include only the third light-emitting portion 123 that emits blue light.

In addition, the first light-emitting portion 121 of the first LED stack L1 may have an n-side up form and may be located above the second light-emitting portion 122 of the second LED stack L2, the second light-emitting portion 122 of the second LED stack L2 may have an n-side up form and may be located above the third light-emitting portion 123 of the third LED stack L3, and the upper surface of the first light-emitting portion 121 having nitrogen polarity may be surface textured.

Accordingly, since red light is not absorbed by the other light-emitting portions 120, the light-emitting efficiency of the red light in a vertically stacked tandem structure can be significantly improved.

In addition, since each LED stack L of the present invention has all other light-emitting portions 120 removed except for the light-emitting portion 120 that emits the corresponding color, unwanted sub-pixel light emission caused by light excitation by blue light with a short wavelength may be fundamentally blocked.

Meanwhile, in the present invention, the light-emitting areas of the plurality of LED stacks L may all be the same, and the operating voltages may also all be set to be the same for the plurality of LED stacks L. Typically, each light-emitting portion 120 that emits red, green or blue does not have the same operating voltage. However, assuming that the operating voltage of each light-emitting portion 120 is 3 V, although the present invention has a stacked structure, since the series connection is all disconnected by conducting current through the short passage 180, it becomes the same as a parallel structure. Thus, the operating voltages may all be set to the same 3 V.

The forming step S170 is a step of forming a mold portion 150 that fills a space between the plurality of aligned LED stacks L, and then forming the common electrode 160 on the plurality of LED stacks L. In this case, since the light-emitting portions 120 in the present embodiment have an n-side up form, the common electrode 160 may be formed as a negative electrode.

In this case, preferably, before forming the mold portion 150 that fills the space between the plurality of aligned LED stacks L, a passivation process, that is, a process of covering the side surfaces of all light-emitting portions 120 with an optically transparent and electrically insulating material (for example, SiO2, SiNx, or Al2O3), may be performed.

More specifically, in the forming step S170, the mold portion 150 may be formed between and above the plurality of aligned LED stacks L, the mold portion 150 may be etched so that upper portions of the plurality of LED stacks L are exposed, and then the common electrode 160 may be formed to be in contact with the upper portions of the plurality of LED stacks L, thereby completing a vertically stacked LEDOS structure. Here, the common electrode 160 may be formed of a material having transparent conductivity similar to the ohmic contact electrode 124, and when the common electrode 160 is a negative electrode, the material of the common electrode 160 may include TIN, CrN, VN, In2O3, SnO2, ZnO, IZO, ITO, and IGZO.

Additionally, the surface of the common electrode 160 may also be polished to a smooth flat surface through mechanical polishing (MP) or chemical-mechanical polishing (CMP).

Furthermore, although not shown, a protective layer made of a transparent organic material may be additionally formed to protect the common electrode 160 from the atmospheric environment.

Hereinafter, a vertically stacked microdisplay panel 100 according to the first embodiment of the present invention will be described in detail with reference to the attached drawings.

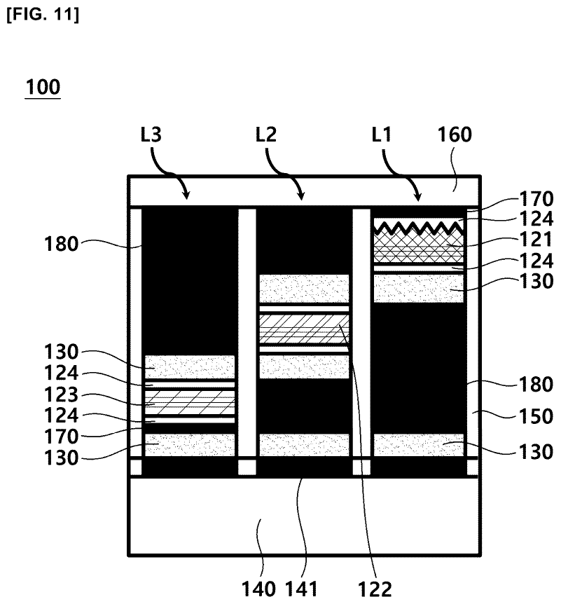

FIG. 11 shows the vertically stacked microdisplay panel according to the first embodiment of the present invention.

As shown in FIG. 11, the vertically stacked microdisplay panel 100 according to the first embodiment of the present invention may include a back wafer 140, a plurality of LED stacks L, a mold portion 150, and a common electrode 160, wherein the common electrode 160 is a negative electrode.

Hereinafter, some of the overlapping content with the method S100 of manufacturing a vertically stacked microdisplay panel according to the first embodiment of the present invention will be omitted.

The back wafer 140 is an active driving IC driven by an active matrix (AM) method, and refers to a CMOS wafer in which a plurality of CMOS electrode pads 141 are arranged on an upper surface in an array. A passivation layer may be formed on an upper surface of the back wafer 140, and a portion of the passivation layer may be etched so that the plurality of CMOS electrode pads 141 are exposed when bonding a front wafer 110.

The plurality of LED stacks L may include light-emitting portions 120 having an ohmic contact electrode 124 on each of the upper and lower surfaces, which are vertically stacked through bonding layers 130, and may be respectively aligned on the plurality of CMOS electrode pads 141.

Specifically, the plurality of LED stacks L may include a first LED stack L1 for emitting only a first color, a second LED stack L2 for emitting only a second color, and a third LED stack L3 for emitting only a third color.

In this case, the first LED stack L1 may be formed to have a short passage 180 such that the region of the third light-emitting portion 123 including ohmic contact electrodes 124 on the upper and lower surfaces and the region of the second light-emitting portion 122 including ohmic contact electrodes 124 on the upper and lower surfaces are removed so that a current flows only through the first light-emitting portion 121 to emit only a first color, and when a transmissive layer 170 is formed on the first light-emitting portion 121, the transmissive layer 170 may transmit the first color generated in the first light-emitting portion 121.

In addition, the second LED stack L2 may be formed to have a short passage 180 such that the region of the first light-emitting portion 121 including ohmic contact electrodes 124 on the upper and lower surfaces and the region of the third light-emitting portion 123 including ohmic contact electrodes 124 on the upper and lower surfaces are removed so that a current flows only through the second light-emitting portion 122 to emit only a second color.

In addition, the third LED stack L3 may be formed to have a short passage 180 such that the region of the first light-emitting portion 121 including ohmic contact electrodes 124 on the upper and lower surfaces and the region of the second light-emitting portion 122 including ohmic contact electrodes 124 on the upper and lower surfaces are removed so that a current flows only through the third light-emitting portion 123 to emit only a third color and a transmissive layer 170 is formed below the third light-emitting portion 123.

Accordingly, the first LED stack L1 of the present invention may include only a first light-emitting portion 121 that emits red light, the second LED stack L2 may include only a second light-emitting portion 122 that emits green light, and the third LED stack L3 may include only a third light-emitting portion 123 that emits blue light.

In addition, the first light-emitting portion 121 of the first LED stack L1 may have an n-side up form and may be located above the second light-emitting portion 122 of the second LED stack L2, the second light-emitting portion 122 of the second LED stack L2 may have an n-side up form and may be located above the third light-emitting portion 123 of the third LED stack L3, and the upper surface of the first light-emitting portion 121 having nitrogen polarity may be surface textured.

Accordingly, since red light is not absorbed by the other light-emitting portions 120, the light-emitting efficiency of the red light in a vertically stacked tandem structure can be significantly improved.

In addition, since each LED stack L of the present invention has all other light-emitting portions 120 removed except for the light-emitting portion 120 that emits the corresponding color, unwanted sub-pixel light emission caused by light excitation by blue light with a short wavelength may be fundamentally blocked.

The mold portion 150 supports the vertically stacked LEDOS structure and is formed to fill the space between the plurality of aligned LED stacks L.

The common electrode 160 is provided as a negative electrode and is formed on the plurality of LED stacks L in which the mold portion 150 is formed, and may be formed to be in contact with upper portions of the plurality of LED stacks L and may be formed of a material having transparent conductivity similar to the ohmic contact electrode 124, and when the common electrode 160 is a negative electrode, the material of the common electrode 160 may include TiN, CrN, VN, In2O3, SnO2, ZnO, IZO, ITO, and IGZO.

Hereinafter, a method S200 of manufacturing a vertically stacked microdisplay panel according to a second embodiment of the present invention will be described in detail with reference to the attached drawings.

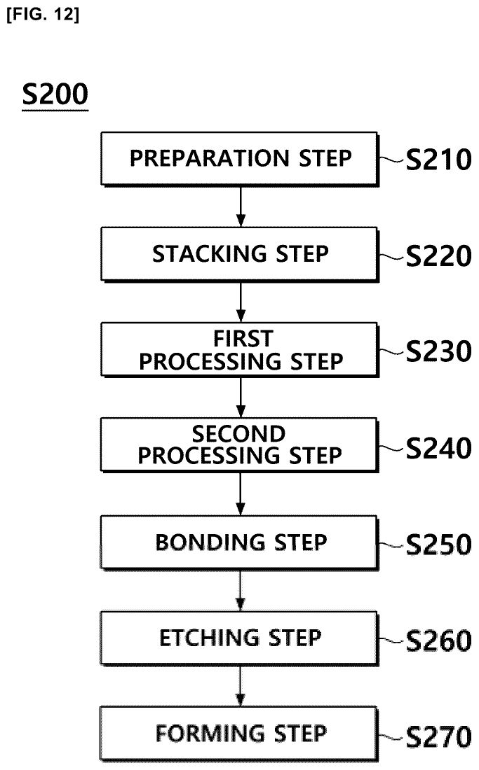

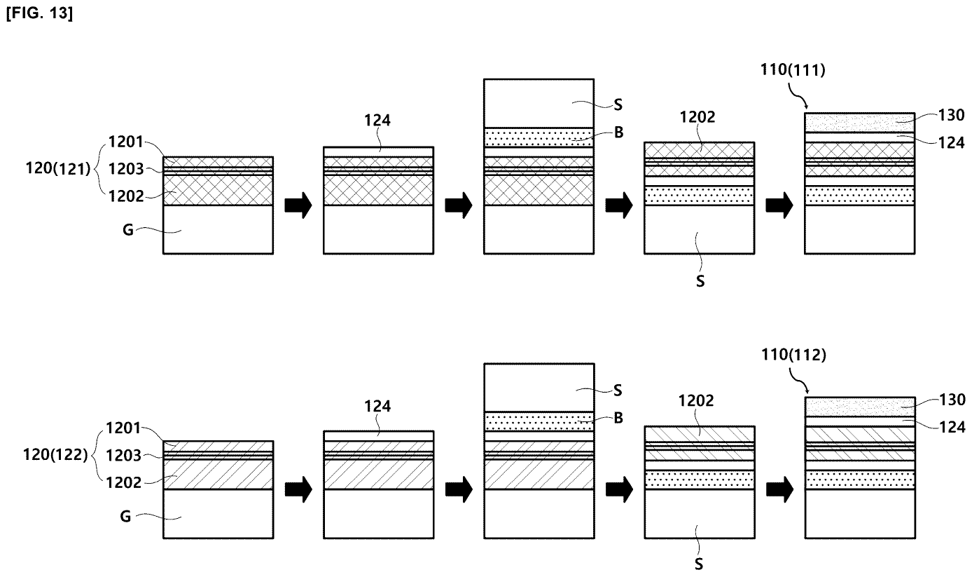

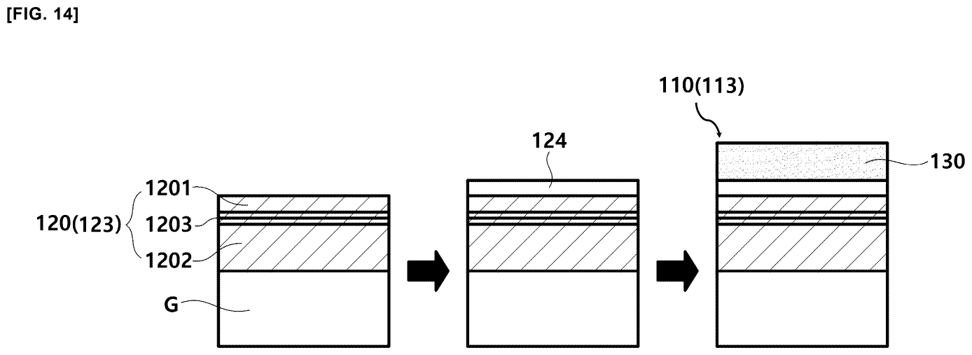

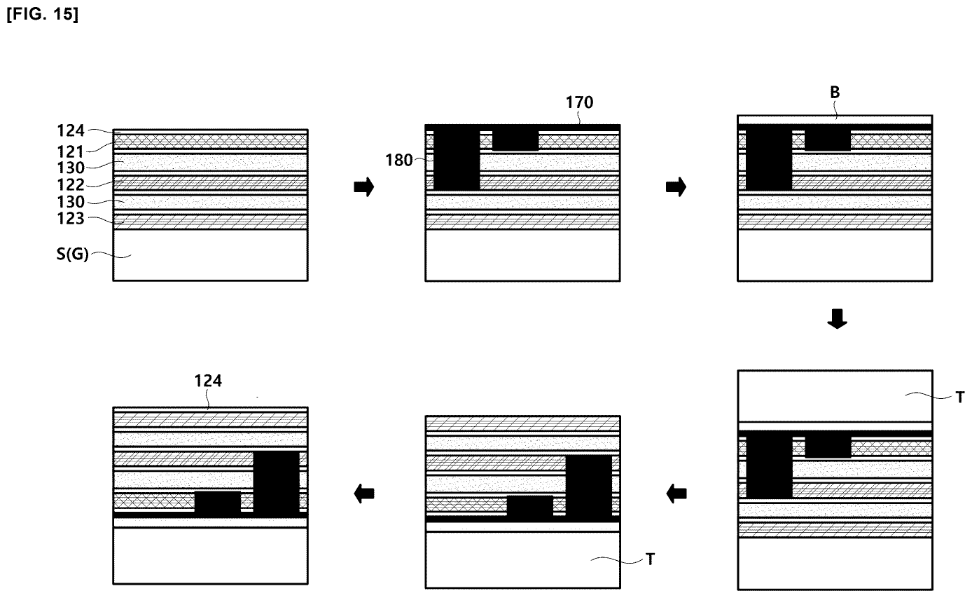

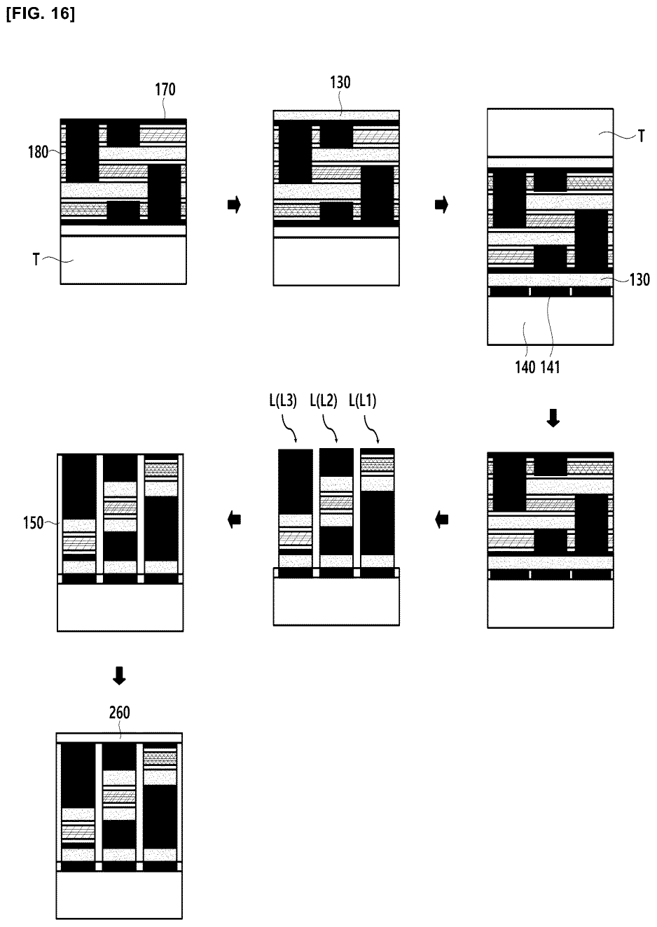

FIG. 12 is a flowchart for describing the method S200 of manufacturing a vertically stacked microdisplay panel according to the second embodiment of the present invention, FIGS. 13 and 14 show a process of preparing a front wafer 210 in the method S200 of manufacturing a vertically stacked microdisplay panel according to the second embodiment of the present invention, and FIGS. 15 and 16 show a process of manufacturing a vertically stacked microdisplay panel according to the method S200 of manufacturing a vertically stacked micro-display panel according to the second embodiment of the present invention.

As shown in FIGS. 12 to 16, the method S200 of manufacturing a vertically stacked microdisplay panel according to the second embodiment of the present invention includes a preparation step S210, a stacking step S220, a first processing step S230, a second processing step S240, a bonding step S250, an etching step S260, and a forming step S270, wherein a common electrode 260 is a positive electrode.

Hereinafter, some of the overlapping content with the manufacturing method S100 of the vertically stacked microdisplay panel according to the first embodiment of the present invention will be omitted.

The preparation step S210 is a step of preparing a plurality of front wafers 210 and a back wafer 140.

The plurality of front wafers 210 are each for emitting different colors, and the plurality of front wafers 210 may include a first front wafer 211 for emitting a first color, a second front wafer 212 for emitting a second color different from the first color, and a third front wafer 213 for emitting a third color different from the first and second colors. Meanwhile, the first color, the second color, and the third color may be, for example, red, green, and blue, respectively, but are not limited thereto, and may include various other colors.

Here, the first front wafer 211 may include a support wafer S and a first light-emitting portion 121 disposed on an upper portion of the support wafer S, the second front wafer 212 may include a support wafer S and a second light-emitting portion 122 disposed on an upper portion of the support wafer S, and the third front wafer 213 may include a support wafer S and a third light-emitting portion 123 disposed on an upper portion of the support wafer S.

As shown in FIG. 13, the process of manufacturing the first front wafer 211 in the present embodiment is as follows.

In the case of the first front wafer 211 for emitting red light, after a second semiconductor region 1202, an active region 1203, and a first semiconductor region 1201 are sequentially epitaxially grown on a GaAs growth wafer G, a p-type ohmic contact electrode 124 having transparent conductivity may be formed on an upper surface of the first semiconductor region 1201, and then a support wafer S and the ohmic contact electrode 124 may be bonded through a bonding layer B. Afterward, the growth wafer G may be separated from the light-emitting portion 120 using a chemical lift off (CLO) technique, the second semiconductor region 1202 may be etched to reduce its thickness, and then an n-type ohmic contact electrode 124 having transparent conductivity may be formed on the surface of the second semiconductor region 1202 whose thickness has been reduced, and a bonding layer 130 may be deposited and formed on the n-type ohmic contact electrode 124, thereby preparing the front wafer 210 in an n-side up form. In this case, the support wafer S may be formed of a Si material having a (111), (110) or (100) crystal plane, but is not limited thereto, and the first front wafer 211 may have a structure in which the support wafer S, the bonding layer B, the ohmic contact electrode 124, the light-emitting portion 120, the ohmic contact electrode 124, and the bonding layer 130 are sequentially stacked.

In addition, as shown in FIG. 13, the process of manufacturing the second front wafer 212 in the present embodiment is as follows.

For the second front wafer 212 for emitting green light, after sequentially epitaxially growing a second semiconductor region 1202, an active region 1203, and a first semiconductor region 1201 on a sapphire (α-phase Al2O3) growth wafer G, a p-type ohmic contact electrode 124 having transparent conductivity may be formed on an upper surface of the first semiconductor region 1201, and then a support wafer S and the ohmic contact electrode 124 may be bonded through a bonding layer B. Afterward, the growth wafer G may be separated from the light-emitting portion 120 using a laser lift off (LLO) technique, the second semiconductor region 1202 may be etched to reduce its thickness, and then an n-type ohmic contact electrode 124 having transparent conductivity may be formed on the surface of the second semiconductor region 1202 whose thickness has been reduced, and a bonding layer 130 may be deposited and formed on the n-type ohmic contact electrode 124, thereby preparing the front wafer 210 in an n-side up form. In this case, the support wafer S may be formed of a Si material having a (111), (110) or (100) crystal plane, but is not limited thereto, and the second front wafer 212 may have a structure in which the support wafer S, the bonding layer B, the ohmic contact electrode 124, the light-emitting portion 120, the ohmic contact electrode 124, and the bonding layer 130 may be sequentially stacked.

In addition, as shown in FIG. 14, the process of manufacturing the third front wafer 213 in the present embodiment is as follows.

For the third front wafer 213 for emitting blue light, after sequentially epitaxially growing a second semiconductor region 1202, an active region 1203, and a first semiconductor region 1201 on a sapphire (α-phase Al2O3) growth wafer G, which is an optically transparent wafer with high-temperature heat resistance through which 100% of a laser beam (single-wavelength light) is transmitted without absorption (in theory), a p-type ohmic contact electrode 124 having transparent conductivity may be formed on an upper surface of the first semiconductor region 1201, and then a bonding layer 130 having transparent conductivity may be deposited and formed on the ohmic contact electrode 124, thereby preparing the front wafer 210 in a p-side up form. In this case, the growth wafer G serves as a support wafer S, and the third front wafer 213 may have a structure in which the support wafer S, the light-emitting portion 120, the ohmic contact electrode 124, and the bonding layer 130 are sequentially stacked.

The back wafer 140 is an active driving IC driven by an active matrix (AM) method, and refers to a CMOS wafer in which a plurality of CMOS electrode pads 141 are arranged on an upper surface in an array, as shown in FIG. 8. A passivation layer may be formed on an upper surface of the back wafer 140 so that upper surfaces of the plurality of CMOS electrode pads 141 are not exposed, and a portion of the passivation layer may be etched so that the plurality of CMOS electrode pads 141 are exposed when the front wafer 210 is bonded.

The stacking step S220 is a step of vertically stacking a plurality of light-emitting portions 120 on a support wafer S by repeatedly bonding another front wafer 210 on one front wafer 210 through a bonding layer 130 and then removing the support wafer S of the other front wafer 210.

As shown in FIG. 15, specifically, in the stacking step S220 of the present embodiment, first, a second front wafer 212 in an n-side up form that emits green light may be bonded to a third front wafer 213 in a p-side up form that emits blue light through a bonding layer 130, and then, a support wafer S of the second front wafer 212 may be removed using laser lift-off or the like, and a bonding layer 130 may be deposited on a p-type ohmic contact electrode 124.

Afterward, after a first front wafer 211 in a p-side up form that emits red light is bonded through the bonding layer 130, the support wafer S of the first front wafer 211 may be removed using chemical lift-off or the like so that the p-type ohmic contact electrode 124 is exposed to the outside.

Subsequently, heat treatment should be performed at a high temperature of 200 to 900° C. to improve the bonding strength of the transparent conductive ceramic bonding layer 130. That is, in the present invention, after all RGB light sources are stacked on the support wafer S (initial growth wafer G), high-temperature heat treatment may be performed to secure the bonding strength between the RGB epitaxial layers, and then the RGB stacked structure may be bonded to a CMOS Si back wafer 140 at one time.

Through this, the support wafer S, the third light-emitting portion 123 having the ohmic contact electrode 124 formed on the upper surface, the bonding layer 130, the second light-emitting portion 122 having the ohmic contact electrode 124 formed on each of the upper and lower surfaces, the bonding layer 130, and the first light-emitting portion 121 having the ohmic contact electrode 124 formed on each of the upper and lower surfaces are stacked in the vertical direction, and the stack may secure strong bonding strength between the RGB epitaxial layers through heat treatment at a high temperature.

The first processing step S230 is a step of forming a short passage 180 in a partial region from one side (that is, the first light-emitting portion 121 side) of the plurality of stacked light-emitting portions 120.

Specifically, in the first processing step S230, after forming a through hole in the region where a third LED stack L3 is to be formed to pass through the first light-emitting portion 121, the ohmic contact electrodes 124 on the upper and lower surfaces of the first light-emitting portion 121, and the bonding layer 130 below the first light-emitting portion, and then pass through the second light-emitting portion 122 and the ohmic contact electrodes 124 on the upper and lower surfaces of the second light-emitting portion 122 (or pass through the bonding layer 130 below the second light-emitting portion 122), the short passage 180 is formed by filling the through hole with an optically transparent and electrically conductive transmissive material. In addition, in the first processing step S230, after forming a through hole in the region where a second LED stack L2 is to be formed to pass through the first light-emitting portion 121 and the ohmic contact electrodes 124 on the upper and lower surfaces of the first light-emitting portion 121 (or pass through the bonding layer 130 below the first light-emitting portion 121), the short passage 180 may be formed by filling the through hole with a conductive transmissive material. In addition, in the first processing step S230, after filling the through hole with a conductive transmissive material, this material may be left on the ohmic contact electrode 124 so that a transmissive layer 170 is formed in the region where a first LED stack L1 is to be formed.

The second processing step S240 is a step of forming a short passage 180 in a partial region from the other side of the plurality of stacked light-emitting portions 120.

Specifically, in the second processing step S240, after bonding a temporary wafer T to one surface of the plurality of stacked light-emitting portions 120 through a bonding layer B, a lower support wafer S may be separated using laser lift-off or the like. In addition, after etching the exposed second semiconductor region 1202 of the third light-emitting portion 123 to reduce the thickness of the second semiconductor region 1202, an n-type ohmic contact electrode 124 having transparent conductivity may be formed on the surface of the second semiconductor region 1202 whose thickness has been reduced.

Thereafter, in the second processing step S240, a short passage 180 may be formed on the other surface of the plurality of stacked light-emitting portions 120 (that is, the third light-emitting portion 123 side). Specifically, after forming the through hole to extend in the region where the first LED stack L1 is to be formed to pass through the third light-emitting portion 123 and the ohmic contact electrodes 124 on the upper and lower surfaces of the third light-emitting portion 123, and the bonding layer 130, and then pass through the second light-emitting portion 122 and the ohmic contact electrodes 124 on the upper and lower surfaces of the second light-emitting portion 122 (or pass through a bonding layer 130 below the second light-emitting portion 122), the short passage 180 may be formed by filling the through hole with an optically transparent and electrically conductive transmissive material. In addition, in the second processing step S240, after forming the through hole in the region where the second LED stack L2 is to be formed to pass through the third light-emitting portion 123 and the ohmic contact electrodes 124 on the upper and lower surfaces of the third light-emitting portion 123 (or pass through a bonding layer 130 under the third light-emitting portion 123), the short passage 180 may be formed by filling the through hole with a conductive transmissive material. In addition, in the second processing step S240, after filling the through hole with a transparent and electrically conductive material, a transmissive layer 170 may be formed in the region where the third LED stack L3 is to be formed by leaving this material on the ohmic contact electrode 124.

In this case, a width of the through hole, that is, a width of the short passage 180, may be formed to correspond to a width of the LED stack L to be formed in the same manner as in the first processing step S230 or a width of the light-emitting portion 120 of the formed LED stack L.

The bonding step S250 is a step in which, after the second processing step S240, the temporary wafer T on which the plurality of light-emitting portions 120 are stacked in the vertical direction is bonded to the back wafer 140 through the bonding layer 130, and then the temporary wafer T is removed.

After the temporary wafer T and the back wafer 140 are bonded, heat treatment of the bonding layer 130 should be performed at a temperature below 400° C. to prevent damage a CMOS circuit of the back wafer 140, and the removal of the temporary wafer T may be accomplished using techniques such as mechanical polishing (MP) and chemical lift off (CLO). Meanwhile, when a sapphire temporary wafer T is used as the temporary wafer T, it is of course possible to remove the temporary wafer T using a laser lift off (LLO) technique.

Accordingly, in the present invention, the third light-emitting portion 123 that emits blue light, the second light-emitting portion 122 that emits green light, and the first light-emitting portion 121 that emits red light are sequentially stacked in a p-side up form on the back wafer 140.

The etching step S260 is a step in which a plurality of light-emitting portions 120, ohmic contact electrodes 124, and bonding layers 130 which have been stacked are etched to separate the light-emitting portions 120, the ohmic contact electrodes 124, and the bonding layers 130 into preset units, thereby allowing the plurality of LED stacks L to be respectively disposed and aligned on the plurality of CMOS electrode pads 141.

Meanwhile, the plurality of LED stacks L may include a first LED stack L1 for emitting only a first color, a second LED stack L2 for emitting only a second color, and a third LED stack L3 for emitting only a third color.

After the above-described etching step S260 has been performed, the short passage 180 may be formed in the first LED stack L1 so that the region of the third light-emitting portion 123 including ohmic contact electrodes 124 on the upper and lower surfaces and the region of the second light-emitting portion 122 including ohmic contact electrodes 124 on the upper and lower surfaces are removed. Thus, a current may flow only through the first light-emitting portion 121 to emit only a first color, and when the transmissive layer 170 may be formed on the first light-emitting portion 121, the transmissive layer 170 may transmit the first color generated in the first light-emitting portion 121.

In addition, a short passage 180 may be formed in the second LED stack L2 so that the region of the first light-emitting portion 121 including ohmic contact electrodes 124 on the upper and lower surfaces and the region of the third light-emitting portion 123 including ohmic contact electrodes 124 on the upper and lower surfaces are removed. Thus, a current may flow only through the second light-emitting portion 122 to emit only a second color.

In addition, a short passage 180 may be formed in the third LED stack L3 so that the region of the first light-emitting portion 121 including ohmic contact electrodes 124 on the upper and lower surfaces and the region of the second light-emitting portion 122 including ohmic contact electrodes 124 on the upper and lower surfaces are removed. Thus, a current may flow only through the third light-emitting portion 123 to emit only a third color, and the transmissive layer 170 may be formed on a lower portion of the third light-emitting portion 123.

Accordingly, the first LED stack L1 of the present invention may include only a first light-emitting portion 121 that emits red light, the second LED stack L2 may include only a second light-emitting portion 122 that emits green light, and the third LED stack L3 may include only a third light-emitting portion 123 that emits blue light.

In addition, the first light-emitting portion 121 of the first LED stack L1 may have a p-side up form and may be located above the second light-emitting portion 122 of the second LED stack L2, and the second light-emitting portion 122 of the second LED stack L2 may have a p-side up form and may be located above the third light-emitting portion 123 of the third LED stack L3.

Accordingly, since red light is not absorbed by the other light-emitting portions 120, the light-emitting efficiency of the red light in a vertically stacked tandem structure can be significantly improved.

In addition, since each LED stack L of the present invention has all other light-emitting portions 120 removed except for the light-emitting portion 120 that emits the corresponding color, unwanted sub-pixel light emission caused by light excitation by blue light with a short wavelength may be fundamentally blocked.

The forming step S270 is a step of forming a mold portion 150 that fills the space between the plurality of aligned LED stacks L, and then forming the common electrode 260 on the plurality of LED stacks L. In this case, since the light-emitting portions 120 in the present embodiment have a p-side up form, the common electrode 260 may be formed as a positive electrode. Here, the common electrode 260 may be formed of a material having transparent conductivity similar to the ohmic contact electrode 124, and when the common electrode 260 is a positive electrode, the material of the common electrode 260 may include NiO, PtO, PdO, AgO2, Au, Rh2O3, RuO2, In2O3, SnO2, ZnO, IZO, ITO, and IGZO.

Hereinafter, a vertically stacked microdisplay panel 200 according to a second embodiment of the present invention will be described in detail with reference to the attached drawings.

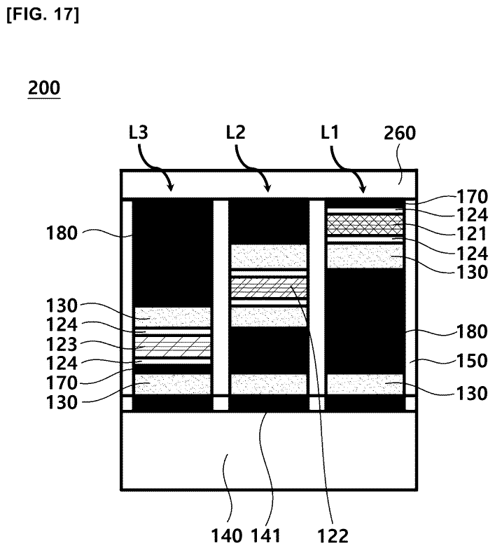

FIG. 17 shows the vertically stacked microdisplay panel 200 according to the second embodiment of the present invention.

As shown in FIG. 17, the vertically stacked microdisplay panel 200 according to the second embodiment of the present invention includes a back wafer 140, a plurality of LED stacks L, a mold portion 150, and a common electrode 260, wherein the common electrode 260 is a positive electrode.

Hereinafter, some of the overlapping content with the method S200 of manufacturing a vertically stacked microdisplay panel according to the second embodiment of the present invention will be omitted.

The back wafer 140 is an active driving IC driven by an active matrix (AM) method, and refers to a CMOS wafer in which a plurality of CMOS electrode pads 141 are arranged on an upper surface in an array. A passivation layer may be formed on an upper surface of the back wafer 140, and a portion of the passivation layer may be etched so that the plurality of CMOS electrode pads 141 are exposed when bonding a front wafer 210.

The plurality of LED stacks L may each include light-emitting portions 120 having ohmic contact electrodes 124 on the upper and lower surfaces, which are vertically stacked through a bonding layer 130, and may be respectively aligned on the plurality of CMOS electrode pads 141.

Specifically, the plurality of LED stacks L may include a first LED stack L1 for emitting only a first color, a second LED stack L2 for emitting only a second color, and a third LED stack L3 for emitting only a third color.

In this case, a short passage 180 may be formed in the first LED stack L1 so that the region of a third light-emitting portion 123 including ohmic contact electrodes 124 on the upper and lower surfaces and the region of a second light-emitting portion 122 including ohmic contact electrodes 124 on the upper and lower surfaces are removed. Thus, a current may flow only through a first light-emitting portion 121 to emit only a first color, and when a transmissive layer 170 is formed on the first light-emitting portion 121, the transmissive layer 170 may transmit the first color generated in the first light-emitting portion 121.

In addition, a short passage 180 may be formed in the second LED stack L2 so that the region of a first light-emitting portion 121 including ohmic contact electrodes 124 on the upper and lower surfaces and the region of a third light-emitting portion 123 including ohmic contact electrodes 124 on the upper and lower surfaces are removed. Thus, a current may flow only through a second light-emitting portion 122 to emit only a second color.

In addition, a short passage 180 may be formed in the third LED stack L3 so that the region of a first light-emitting portion 121 including ohmic contact electrodes 124 on the upper and lower surfaces and the region of a second light-emitting portion 122 including ohmic contact electrodes 124 on the upper and lower surfaces are removed. Thus, a current may flow through a third light-emitting portion 123 to emit only a third color, and a transmissive layer 170 may be formed below the third light-emitting portion 123.

Accordingly, the first LED stack L1 of the present invention may include only the first light-emitting portion 121 that emits red light, the second LED stack L2 may include only the second light-emitting portion 122 that emits green light, and the third LED stack L3 may include only the third light-emitting portion 123 that emits blue light.

In addition, the first light-emitting portion 121 of the first LED stack L1 may have a p-side up form and may be located above the second light-emitting portion 122 of the second LED stack L2, and the second light-emitting portion 122 of the second LED stack L2 may have a p-side up form and may be located above the third light-emitting portion 123 of the third LED stack L3.

Accordingly, since red light is not absorbed by the other light-emitting portions 120, the light-emitting efficiency of the red light in a vertically stacked tandem structure can be significantly improved.

In addition, since each LED stack L of the present invention has all other light-emitting portions 120 removed except for the light-emitting portion 120 that emits the corresponding color, unwanted sub-pixel light emission caused by light excitation by blue light with a short wavelength may be fundamentally blocked.

The mold portion 50 supports the vertically stacked LEDOS structure and is formed to fill the space between the plurality of aligned LED stacks L.

The common electrode 260 is provided as a positive electrode and is formed on the plurality of LED stacks L in which the mold portion 150 is formed, and is formed to be in contact with upper portions of the plurality of LED stacks L, and may be formed of a material having transparent conductivity similar to the ohmic contact electrode 124, and when the common electrode 260 is a positive electrode, the material of the common electrode 260 may include NiO, PtO, PdO, AgO2, Au, Rh2O3, RuO2, In2O3, SnO2, ZnO, IZO, ITO, and IGZO.

According to the present invention, since a color filter is unnecessary despite the adoption of a vertically stacked tandem structure, the color quality of a microdisplay can be significantly improved, and process complexity and productivity can be significantly improved.

Also, according to the present invention, unlike the existing monolithic integration method or hybridization method in which there are alignment issues, an engineering monolithic epitaxy wafer is first manufactured, and then a stack on the engineering monolithic epitaxy wafer is etched to separate the stack into preset units, thereby allowing a plurality of LED stacks to be aligned on a plurality of CMOS electrode pads. Thus, not only a small-diameter wafer of 6 inches or less but also a large-diameter wafer of 8 inches or more can be used so that the product yield can be significantly increased.

Furthermore, according to the present invention, since a bonding layer and an ohmic contact electrode are made of an electrically conductive transparent ceramic material rather than metals, the possibility of an electrical short-circuit failure is significantly reduced, and the reliability of the device is greatly increased. In addition, there is the effect of easily performing etching in a plasma dry process for LED stack alignment while eliminating the problem of etch byproduct redeposition. Furthermore, the above-described ease of etching offers significant advantages in the production of high-resolution microdisplays with ultra-fine pixels less than 3 μm.

Moreover, according to the present invention, a light-emitting portion, a bonding layer, and an ohmic contact electrode are all transparent, allowing visible light to pass therethrough, thereby eliminating alignment errors during an exposure process.

Also, according to the present invention, the light-emitting efficiency of red light in a vertically stacked tandem structure can be significantly improved.

Furthermore, since all other light-emitting portions are removed except for a light-emitting portion that emits a corresponding color in each LED stack of the present invention, unwanted sub-pixel light emission caused by light excitation occurring by blue light with a short wavelength can be fundamentally blocked.

Meanwhile, the effects of the present invention are not limited to the above-described effects, and various other effects may be included within a scope apparent to those skilled in the art from the description below.

Although all components constituting the embodiments of the present invention have been described as being combined or operating in combination as one, the present invention is not necessarily limited to such embodiments. That is, all of the components may be selectively combined and operated in one or more combinations within the scope of the present invention.

Furthermore, terms such as “comprise,” “include,” or “have” described above, unless specifically stated otherwise, imply that the corresponding component may be present, and therefore should be interpreted to include other components rather than excluding other components. All terms, including technical or scientific terms, have the same meaning as commonly understood by a person of ordinary skill in the art to which the present invention pertains, unless otherwise defined. Commonly used terms, such as terms defined in dictionaries, should be interpreted to be consistent with the contextual meaning of the related art, and shall not be interpreted in an ideal or overly formal sense, unless explicitly defined in the present invention.

Further, the above description is merely an example of the technical idea of the present invention, and those skilled in the art will appreciate that various modifications and variations can be made without departing from the essential characteristics of the present invention.

Accordingly, the embodiments disclosed in the present invention are intended to illustrate, rather than limit, the technical concept of the present invention, and the scope of the technical concept of the present invention is not limited by these embodiments. The scope of protection of the present invention should be interpreted by the following claims, and all technical concepts within the scope equivalent thereto should be construed as being included within the scope of the present invention.

What is claimed is:

1. A vertically stacked microdisplay panel comprising:
a back wafer having a plurality of complementary metal-oxide semiconductor (CMOS) electrode pads aligned on an upper surface;
a plurality of light-emitting diode (LED) stacks each including a light-emitting portion stacked in a vertical direction through a bonding layer and respectively aligned on the plurality of CMOS electrode pads; and
a common electrode formed on the plurality of LED stacks,
wherein the plurality of LED stacks include a first LED stack including a first light-emitting portion that emits a first color, a second LED stack including a second light-emitting portion that emits a second color, and a third LED stack including a third light-emitting portion that emits a third color,
each of the plurality of LED stacks has a short passage formed in a region so that a current flows through the light-emitting portion where the short passage is not formed, thereby emitting only a specific color,
the first light-emitting portion of the first LED stack is located above the second light-emitting portion of the second LED stack and the third light-emitting portion of the third LED stack, and
the first light-emitting portion emits red light.

2. The vertically stacked microdisplay panel of claim 1, wherein a width of the short passage is formed to correspond to a width of the light-emitting portion.

3. The vertically stacked microdisplay panel of claim 1, wherein the common electrode is a negative electrode or a positive electrode.

4. A method of manufacturing a vertically stacked microdisplay panel, comprising:
a preparation step of preparing a plurality of front wafers including a support wafer and a light-emitting portion and a back wafer having a plurality of CMOS electrode pads aligned on an upper surface;
a stacking step of vertically stacking a plurality of light-emitting portions on the support wafer by repeatedly bonding another front wafer on one front wafer through a bonding layer and then removing the support wafer of the other front wafer;
a first processing step of forming a short passage in a partial region from one side of the plurality of stacked light-emitting portions;
a bonding step of bonding the plurality of stacked light-emitting portions to the back wafer, and then removing the support wafer to stack the plurality of light-emitting portions on the back wafer;
a second processing step of forming a short passage in a partial region from the other side of the plurality of stacked light-emitting portions;
an etching step of etching the plurality of stacked light-emitting portions and separating the plurality of stacked light-emitting portions into preset units, thereby allowing the plurality of LED stacks to be respectively aligned on the plurality of CMOS electrode pads; and
a forming step of forming a common electrode on the plurality of LED stacks,
wherein the plurality of LED stacks include a first LED stack including a first light-emitting portion that emits a first color, a second LED stack including a second light-emitting portion that emits a second color, and a third LED stack including a third light-emitting portion that emits a third color,
each of the plurality of LED stacks has a short passage formed in a region so that a current flows through the light-emitting portion where the short passage is not formed, thereby emitting only a specific color,
the first light-emitting portion of the first LED stack is located above the second light-emitting portion of the second LED stack and the third light-emitting portion of the third LED stack, and
the first light-emitting portion emits red light.

5. The method of claim 4, wherein a width of the short passage is formed to correspond to a width of the light-emitting portion.

6. The method of claim 4, wherein the common electrode is a negative electrode.

7. A method of manufacturing a vertically stacked microdisplay panel, comprising:
a preparation step of preparing a plurality of front wafers including a support wafer and a light-emitting portion and a back wafer having a plurality of CMOS electrode pads aligned on an upper surface;
a stacking step of vertically stacking a plurality of light-emitting portions on the support wafer by repeatedly bonding another front wafer on one front wafer through a bonding layer and then removing the support wafer of the other front wafer;
a first processing step of forming a short passage in a partial region from one side of the plurality of stacked light-emitting portions;
a second processing step of forming a short passage in a partial region from the other side of the plurality of stacked light-emitting portions;
a bonding step of bonding the plurality of stacked light-emitting portions to the back wafer, and then removing the support wafer to stack the plurality of light-emitting portions on the back wafer;
an etching step of etching the plurality of stacked light-emitting portions and separating the plurality of stacked light-emitting portions into preset units, thereby allowing the plurality of LED stacks to be respectively aligned on the plurality of CMOS electrode pads; and
a forming step of forming a common electrode on the plurality of LED stacks,
wherein the plurality of LED stacks include a first LED stack including a first light-emitting portion that emits a first color, a second LED stack including a second light-emitting portion that emits a second color, and a third LED stack including a third light-emitting portion that emits a third color,
each of the plurality of LED stacks has a short passage formed in a region so that a current flows through the light-emitting portion where the short passage is not formed, thereby emitting only a specific color,
the first light-emitting portion of the first LED stack is located above the second light-emitting portion of the second LED stack and the third light-emitting portion of the third LED stack, and
the first light-emitting portion emits red light.

8. The method of claim 7, wherein a width of the short passage is formed to correspond to a width of the light-emitting portion.

9. The method of claim 7, wherein the common electrode is a positive electrode.
